(19) United States
(12) Patent Application Publication
(10) Pub. No.: US 2010/0147347 A1
(43) Pub. Date: Jun. 17, 2010

(54) METHOD AND STRUCTURE FOR HYBRID THERMAL SOLAR MODULE

(75) Inventors: JOHN JAMES DYREBY, Berkeley, CA (US); Joshua Reed Plaisted, Oakland, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: PVT SOLAR, INC., Berkeley, CA (US)

(21) Appl. No.: 12/638,967

(22) Filed: Dec. 15, 2009

Related U.S. Application Data
(60) Provisional application No. 61/122,732, filed on Dec. 16, 2008.

(51) Int. Cl. H01L 31/042; H01L 35/00

(52) U.S. Cl. 136/200; 136/244

(57) ABSTRACT

A solar module assembly and method. The assembly comprises a substantially transparent or semi-transparent surface provided on a first substrate member. The assembly includes an absorber material overlying a second substrate member. A spacing is provided between the semi-transparent surface of the first substrate and the second substrate, which has a first side and a second side. In a specific embodiment, the assembly has a fluid transport region disposed within a vicinity of either the first side or the second side of the second substrate. In a preferred embodiment, the assembly has a photovoltaic device configured from at least the absorber material to generate electrical energy and a thermal energy device configured from at least the absorber material to generate thermal energy using the a fluid provided in the fluid transport region.

### CROSS-REFERENCES TO RELATED APPLICATIONS

This application claims priority to U.S. Provisional Application No. 61/122,732, filed Dec. 16, 2008, commonly assigned, and incorporated by reference herein for all purpose.

### BACKGROUND OF THE INVENTION

The present invention relates to techniques for solar devices. More particularly, the present invention provides a method and system including a combined thin film photovoltaic and thermal solar system, which takes advantage of a single form factor, according to a specific embodiment. Merely, by way of example, the present invention has been applied to a thermal solar module configured on a building structure, but it would be recognized that the invention has a much broader range of applications.

Over the past centuries, the world population of human beings has exploded. Along with the population, demand for resources has also grown explosively. Such resources include raw materials such as wood, iron, and copper and energy, such as fossil fuels, including coal and oil. Industrial countries world wide project more increases in oil consumption for transportation and heating purposes, especially from developing nations such as China and India. Obviously, our daily lives depend, for the most part, upon oil or other fossil fuels, which are being depleted and becoming increasingly scarce.

Along with the depletion of our fossil fuel resources, our planet has experienced a global warming phenomena, known as “global warming,” which was brought to our foremost attention by Al Gore, who is the former Vice President of the United States of America. Global warming is known as an increase in the average temperature of the Earth's air near its surface, which is projected to continue to increase at a rapid pace. Warming is believed to be caused by greenhouse gases, which are derived, in part, from use of fossil fuels. The increase in temperature is expected to cause extreme weather conditions and a drastic size reduction of the polar ice caps, which in turn will lead to higher sea levels and an increase in the rate of warming. Ultimately, other effects include mass species extinctions, and possibly other uncertainties that may be detrimental to human beings.

Much if not all of the useful energy found on the Earth comes from our sun. Generally all common plant life on the Earth achieves life using photosynthesis processes from sun light. Fossil fuels such as oil were also developed from biological materials derived from energy associated with the sun. For most living beings on the Earth, sunlight has been essential. Likewise, the sun has been our most important energy source and fuel for modern day solar energy. Solar energy possesses many characteristics that are very desirable! Solar energy is renewable, clean, abundant, and often readily available.

As an example, solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

From the above, it is seen that techniques for improving operation of a solar system are highly desired.

### BRIEF SUMMARY OF THE INVENTION

According to the present invention, techniques related to solar devices are provided. More particularly, the present invention provides a method and system including a combined thin film photovoltaic and thermal solar system, which takes advantage of a single form factor, according to a specific embodiment. Alternatively, the present method and system can be applied to other types of photovoltaic materials, such as crystalline silicon, polysilicon, organic photovoltaic materials, and others. Merely, by way of example, the present invention has been applied to a thermal solar module configured on a building structure, but it would be recognized that the invention has a much broader range of applications.

In a specific embodiment, the present invention provides a solar module assembly. The assembly comprises a substantially transparent or semi-transparent surface provided on a first substrate member. The assembly includes an absorber material overlying a second substrate member. A spacing is provided between the semi-transparent surface of the first substrate and the second substrate, which has a first side and a second side. In a specific embodiment, the assembly has a fluid transport region disposed within a vicinity of either the first side or the second side of the second substrate. In a preferred embodiment, the assembly has a photovoltaic device configured from at least the absorber material to generate electrical energy and a thermal energy device configured from at least the absorber material to generate thermal energy using the a fluid provided in the fluid transport region. As used herein, the terms “first” and “second” are not intended to imply order but should be construed by ordinary meaning.

In an alternative specific embodiment, the present invention provides a method of using a solar module. The method includes providing a solar system that has a substantially transparent or semi-transparent surface provided on a first substrate member, an absorber material overlying a second substrate member, a spacing provided between the semi-transparent surface of the first substrate and the second substrate, and a fluid transport region disposed within a vicinity of either the first side or the second side of the second substrate. In a preferred embodiment, the system has a photovoltaic device configured from at least the absorber material to generate electrical energy and a thermal energy device configured from at least the absorber material to generate thermal energy using a fluid provided in the fluid transport region. In a specific embodiment, the method includes transferring a volume of the fluid through the transport region from a first region to a second region to cause an increase in enthalpy of the volume of the fluid as the volume of the fluid traverses from the first region to the second region and using the volume of the fluid. Depending upon the embodiment, the volume of heated fluid can be used in a heat exchanger, heating space, heating water, drying cloths, or other applications. Of course, there can be other variations, modifications, and alternatives.

Many benefits are achieved by way of the present invention over conventional techniques. For example, the present technique provides an easy to use process that relies upon conventional technologies such as thin film photovoltaic modules, which can be configured as a thermal solar device. Additionally, the present method provides a process that is compatible with the conventional photovoltaic module without substantial modifications to equipment and processes. Preferably, the invention provides for an improved solar module operation procedure, which is less costly and easy to handle, and has at least electrical and thermal energy generation. In a specific embodiment, the present method and system provides for control of photovoltaic and thermal solar operation. Depending upon the embodiment, thermal energy in the form of heat can be used to improve efficiency of the thin film photovoltaic cell according to an embodiment of the present invention. In other embodiments, the present invention provides a method and structure having an improved efficiency per area of at least 10 percent and greater or 25 percent and greater using a thin film photovoltaic absorber depending upon the application. In a specific embodiment, the present improved efficiency is for a thin film based photovoltaic material, which traditionally has lower efficiencies. In a preferred embodiment, the overall efficiency of the thermal and photovoltaic device, is greater than about 30 percent using a thin film photovoltaic material. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram illustrating a cutaway and a schematic of a simple solar thermal collector according to an embodiment of the present invention;

FIG. 2 is a simplified diagram illustrating a collector device according to an embodiment of the present invention;

FIG. 3 is a simplified diagram illustrating a solar module device according to yet an alternative embodiment of the present invention;

FIG. 4 is a representative plot of typical a-Si photovoltaic efficiency over time according to an embodiment of the present invention;

FIG. 5 is a simplified diagram of a hybrid photovoltaic/thermal system according to an embodiment of the present invention;

FIG. 6 shows a simplified characteristic plot of efficiency for a system that is able to self-anneal according to a specific embodiment; and

FIG. 7 is a simplified diagram illustrating a solar module device with an underlying body according to an embodiment of the present invention.

### DETAILED DESCRIPTION OF THE INVENTION

According to the present invention, techniques related to solar devices are provided. More particularly, the present invention provides a method and system including a combined thin film photovoltaic and thermal solar system, which takes advantage of a single form factor, according to a specific embodiment. Alternatively, the present method and system can be applied to other types of photovoltaic materials, such as crystalline silicon, polysilicon, organic photovoltaic materials, and others. Merely, by way of example, the present invention has been applied to a thermal solar module configured on a building structure, but it would be recognized that the invention has a much broader range of applications.

### Hybrid PV/Thermal Flat-Plate Collector

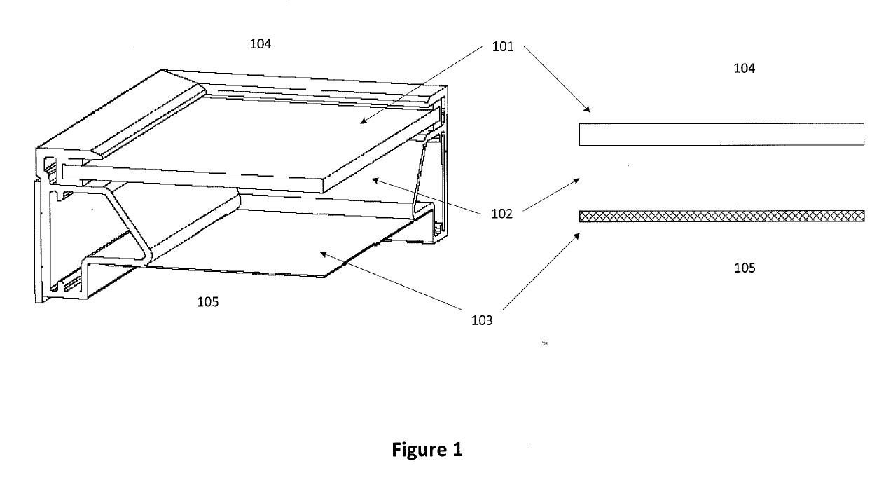

In a specific embodiment of solar thermal collectors, a glazing is used to improve the performance of the collector. As used herein, the term “thermal collectors” can be devices that convert the sun's energy into heat, although there can also be variations, alternatives, and modifications without departing from the scope of the claims herein. FIG. 1 is a simplified diagram illustrating a cutaway and a schematic of a simple solar thermal collector to show an example of a glazing according to a specific embodiment. This diagram is merely an example, which should not unduly limit the scope of the claims herein. One of ordinary skill in the art would recognize other variations, modifications, and alternatives. As used herein, the term “glazing” refers to the use of a semi-transparent cover or substantially transparent cover. In a specific embodiment, a semi-transparent cover (101) or substantially transparent cover is used to create an insulating air gap (102) between the ambient conditions (104) and the absorber (103), which is the part of the collector that absorbs the sun's energy and usually transfers it to a working fluid (105), which may be a gas or a liquid. In a specific embodiment, the cover can be made of a suitable material, which is semi-transparent or substantially transparent. In one or more embodiments, the cover can be made of a glass, such as Solite, a product manufactured by AGC Flat Glass North America, or other low iron glass or water white glass materials, but can be other materials, or alternatively a polymer, such as polycarbonate or acrylic. Of course, there can be other variations, modifications, and alternatives.

In a specific embodiment, the absorber can be made from any suitable material and formed overlying the cover. In a specific embodiment, the cover and the absorber can be made of glass for the cover and a black colored substrate or film for the absorber. Depending upon the embodiment, the present structure can include multiple covers and/or absorbers. In a preferred embodiment, the cover passes all of the electromagnetic energy from the sun to the absorber, which has been isolated from ambient conditions. In a specific embodiment, such isolation can be a gap, which is filled with a vacuum, air, inert gas, or suitable gas, or other suitable material. In a specific embodiment, the isolation facilitates thermal energy transport in the form of heat transfer to the working fluid (105). Of course, there can be other variations, alternatives, and modifications.

In a specific embodiment, the absorber can be made from a material that exhibits a photovoltaic response. In a specific embodiment, the material can be a coating or other suitable layered or layer transferred film. As merely an example, such material can include traditional single crystal or polycrystalline silicon (c-Si) and thin film (or organic) materials such as, amorphous silicon (a-Si), copper indium gallium diselenide (CIGS), copper indium diselenide (CIS), and cadmium telluride (CdTe), among other like photovoltaic materials or any combinations in the form of tandem or multilevel cells. Throughout the present specification, a-Si is used as an example of the photovoltaic material, but anything that exhibits similar properties can replace amorphous silicon. Alternatively, combinations of materials and/or cell configurations can also replace or substitute for amorphous silicon according to a specific embodiment.

In a specific embodiment, the present method and structure has advantages and/or benefits. One or more advantages include the ability to produce both electrical and thermal energy from the same panel and the ability to operate the photovoltaic cells at a higher temperature according to one or more embodiments. With traditional c-Si materials this could be looked at as a disadvantage as the efficiency of the photovoltaic cell typically decreases with temperature, but it has been shown that a-Si type photovoltaic cells maintain a higher conversion (of light to electricity) efficiency at higher temperatures. In other embodiments, thin film cells such as CIGS or CIS also exhibit higher efficiencies after light soaking Of course, there can be other variations, modifications, and alternatives.

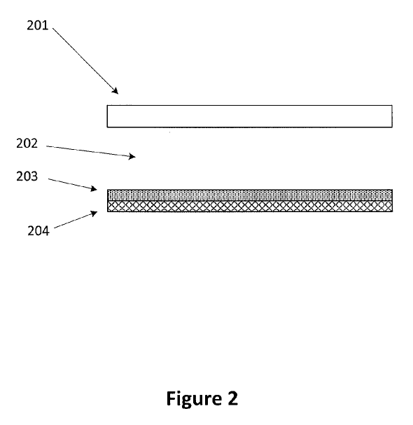

In a specific embodiment of a thin-film photovoltaic material, the collector is constructed (in its simplest form; more complex layering(s) is possible) as shown in a simplified diagram of FIG. 2. This diagram is merely an example, which should not unduly limit the scope of the claims herein. One of ordinary skill in the art would recognize other variations, modifications, and alternatives. In a specific embodiment, the collector can include multiple layers or more complex sequences of materials. As before, the cover (201) creates an insulating air gap (202). In this embodiment, a thin-film a-Si material (203) has been deposited on the absorber base material (204). As noted, any suitable material can be used for the cover (201) and the absorber (204) according to one or more embodiments. Besides the a-Si coated on the absorber surface, other coatings are possible according to other embodiments.

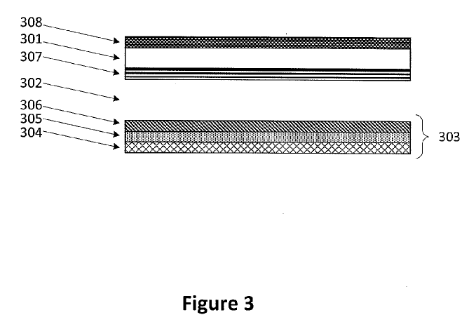

FIG. 3 is a simplified diagram illustrating a solar module device according to yet an alternative embodiment of the present invention. This diagram is merely an example, which should not unduly limit the scope of the claims herein. One of ordinary skill in the art would recognize other variations, modifications, and alternatives. As shown are various examples of the solar device according to a specific embodiment. Depending upon the embodiment, the elements of the embodiments can be combined and matched on various surfaces of the panel. In a specific embodiment, the cover (301) is coated on the top surface with an anti-reflective coating (308) in order to improve transmission through the cover. In one or more embodiments, the antireflective coating can be made of a suitable material such as magnesium fluoride (MgF₂) or fluoropolymers, which can be layered or homogenous. Of course, there can be other variations, modifications, and alternatives. Further coatings and/or surfaces for the elements of the device according to the present invention are described throughout the present specification and more particularly below.

Referring back to FIG. 3, the device includes a bottom of the cover (307) that is preferably coated with a low-emissivity (low-E) material. In a preferred embodiment, the low emissivity material can reduce the energy lost through the cover and increase the temperature of the absorber (303) and air gap (302). In a specific embodiment, the low emissivity material can be silver, tin oxide, or nickel chrome, including layered structures and the like. In a specific embodiment, the absorber base (304) is coated with the a-Si material (305). In a specific embodiment, the a-Si may be coated with a low-emissivity material (306) that limits infrared emittance of thermal energy across the air gap (302) and therefore limits the loss of thermal energy. Of course as noted, depending upon the embodiment, these and other coatings can be used to improve the performance of the hybrid photovoltaic/thermal panel. In a preferred embodiment, the hybrid panel is capable of providing both electrical and thermal energy production. Of course, there can be other variations, modifications, and alternatives.

In a specific embodiment, two or more of the coatings can include adhesives and/or solder layers sandwiched between the two or more coatings. In alternative embodiments, two or more of the coatings are substantially free form any adhesives and/or solder layers sandwiched between them. Although the above has been described in terms of a specific cover and coating structure, other combinations exist including any suitable number of covers or absorbers can be used with any suitable number of coatings. In general according to one or more embodiments, coatings can be any materials (or combinations thereof) that are deposited on the surface to change the physical, optical, thermal, or surface properties of the cover(s) or absorber(s) in the photovoltaic/thermal hybrid solar collector. An example may be a protective encapsulation material for the ‘absorber stack’ deposited in the form of a transparent material such as alumina (Al₂O₃) or other suitable material. The other advantage of this system is that the traditional protective coatings and encapsulations that are often applied to the surface of photovoltaic cells need not be applied. In a solar cell according to a specific embodiment, a substrate is generally required to provide stability, over which cover glass is affixed with adhesives and/or encapsulates in order to protect the active photovoltaic cell layer from the environment. Because the cover (301) of the solar collector provides protection for the cell from ambient, it may not be necessary to cover the cell itself in glass, or at the least, the protection layers may be reduced. Of course, there can be other variations, modifications, and alternatives.

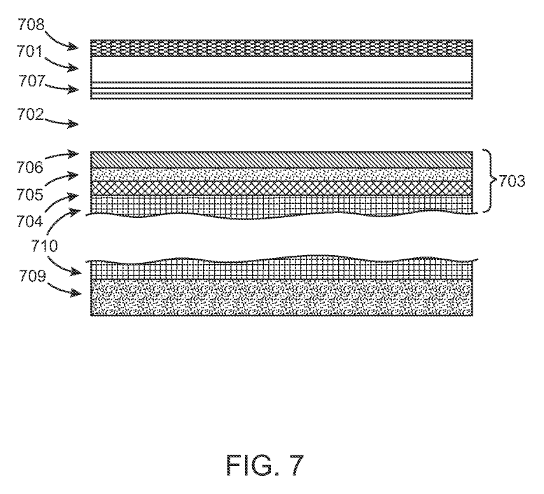

Additionally, in an alternative embodiment, the present module can also include an underlying body either incorporated into the module or the module is mounted on an underlying body. As an example in a solar thermal collector integrated into a photovoltaic/thermal system, the roof is the underlying body. In a specific embodiment, the underlying body is also suspended between the absorber and the roof. As merely an example, FIG. 7 is a simplified diagram illustrating a solar module device with an underlying body according to an embodiment of the present invention. This diagram is merely an example, which should not unduly limit the scope of the claims herein. One of ordinary skill in the art would recognize other variations, modifications, and alternatives. In a specific embodiment, the present underlying body (709) may be coated in a thermoelectric material or infrared tuned photovoltaic cells (710). In a preferred embodiment as shown, the thermoelectric material (711) can be underlying a bottom portion of the absorber material (704) or other suitable spatial configurations. In the case of thermoelectric materials, it has been shown that a temperature difference leads to electrical generation for some materials that exhibit a high figure of merit, Z, (this figure of merit is a combination of a number of different effects, including but not limited to the Seebeck or Peltier effects). In a specific embodiment, the thermoelectric material can be bismuth telluride, or other suitable materials.

In a specific embodiment, the temperature difference between the top surface of the thermoelectric material (711), which is coupled with the bottom surface of the absorber stack (704), and the bottom surface of the thermoelectric material (711), which is radiatively coupled to the underlying body (709), may drive electrical production. In the case of infrared tuned photovoltaic cells, specially designed photovoltaic cells can be mounted or coated (710) on the underlying body (709). These cells would absorb the thermally generated infrared radiation emitted by the bottom surface of the absorber stack (704) and create electricity, thereby increasing the overall electrical production of the panel. Of course, there can be other variations, modifications, and alternatives.

Motivation for Using Amorphous Silicon (a-Si) on the Absorber

Thin film photovoltaic (PV) materials, in particular (but not limited to) amorphous-Si (a-Si) and derivative based materials, have the potential to dramatically reduce the cost of photovoltaic systems (in terms of $/watt installed) due to the potential for massive scalability in manufacturing, especially compared to their traditional, crystal-Silicon (c-Si) counterparts according to one or more embodiments. However, at least two problems prevent mainstream adoption of the technology: low operating efficiency and the tendency of the panels to degrade in the presence of sunlight (known as the Staebler-Wronski effect). Typical a-Si photovoltaic efficiencies are on the order of 6-8 percent, which is much less than c-Si panels (with efficiencies around 12-16 percent). Although research is leading to improvements in thin film photovoltaic efficiency, the Staebler-Wronski effect is still a major concern. Throughout the present specification, a-Si will be used as an example but any material exhibiting a photovoltaic effect impacted by temperature is relevant. Of course, there can be other variations, modifications, and alternatives.

The degradation of an a-Si panel accumulates to a certain point in exposure to sunlight, with typical reductions of efficiency between 10 and 30 percent after stabilization. Stabilization occurs after approximately 1000 hours, which in standard practice is considered to be one year of operation. The Staebler-Wronski effect can be reversed through annealing, but achieving a high enough temperature on commercial or residential photovoltaic applications are not currently practical, especially in constructions where the cell layer is in direct contact with ambient, which reflects the conventional state-of-the-art. Consequently, the operating efficiency of a typical a-Si photovoltaic array is typically 10 to 30 percent below its potential.

In a specific embodiment, constructions similar to that of FIG. 3 where the cell layer is insulated from ambient by an air gap (302) and cover glazing material (301) allow for higher achievable temperatures capable of annealing the photovoltaic cell. As previously mentioned, further thermal insulation of the absorber (305) may be achieved by the application of one or more low-e films (306,307) to limit radiative heat transfer from the absorber (305) to ambient. Further details of various advantages or benefits can be found throughout the present specification and more particularly below.

There are a number of advantages to using a-Si photovoltaic materials on the absorber of a solar collector according to one or more embodiments:

1. Generate both electrical and thermal energy in the same aperture.

2. Reduce the Staebler-Wronski effect due to the higher operating temperature of the cell

3. Ability to “self-anneal” the panel by periodically operating the panel in a stagnation condition to recover from the degraded operating efficiency.

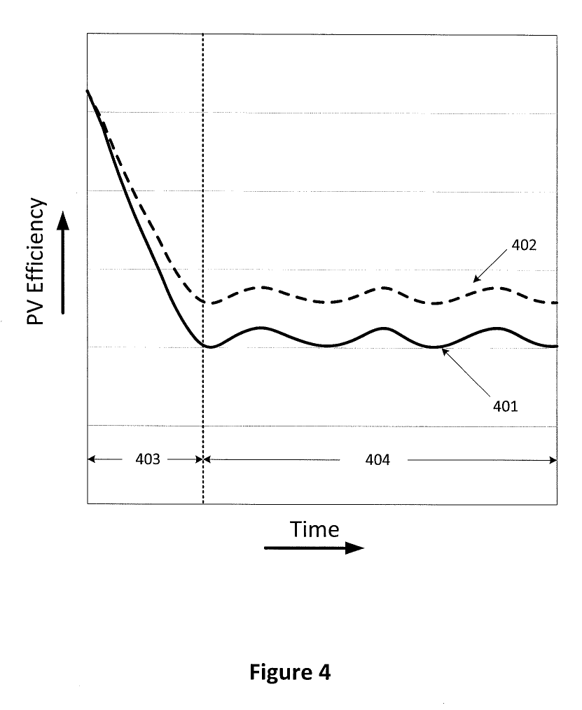

Of course, there can be variations, modifications, and alternatives. Depending upon the embodiment, one or more of these advantages may be achieved. It has been determined that the photo-induced degradation of a-Si cells is slower in warmer climates, indicating the larger the temperature seen by the a-Si the better its performance. FIG. 4 is a representative plot of typical a-Si photovoltaic efficiency over time according to an embodiment of the present invention. This diagram is merely an example, which should not unduly limit the scope of the claims herein. As shown, the solid black line (401) is characteristic of an a-Si panel in a cooler climate, and the dashed line (402) is characteristic of an a-Si panel in a warmer climate. Also shown in the Figure is the Staebler-Wronski effect which degrades the photovoltaic efficiency of the panel over an initial period (403) until it reaches a quasi-steady state efficiency (404). The peaks and troughs in the plot are due to the seasonal temperature change; in winter it is colder (assuming an array in the northern hemisphere) and consequently the efficiency is lower than in the summer when it is warmer. Again, we have provided a simplified illustration.

### Incorporation in PV/Thermal System

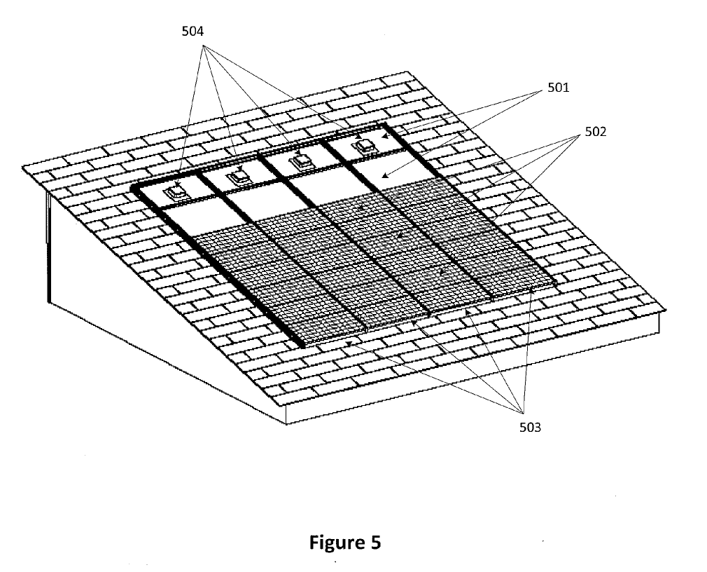

In a specific embodiment, the method and structure described above of a solar collector using photovoltaic material for its absorber can be incorporated into a hybrid photovoltaic/thermal system. The hybrid system could be (but does not necessarily have to be) air-based, as shown in a simplified diagram of FIG. 5. This diagram is merely an example, which should not unduly limit the scope of the claims herein. One of ordinary skill in the art would recognize other variations, modifications, and alternatives. In a specific embodiment, the hybrid photovoltaic/thermal solar collector modules described herein (501) are used with traditional unglazed photovoltaic modules (502) in a hybrid photovoltaic/thermal system where air is drawn in from the bottom of the array (503) and into the building through vents in the top of the array (504). The present system configuration is similar to the photovoltaic/thermal system described by Joshua Reed Plaisted et al. in U.S. Patent Application Publication 2006/0118163A1, commonly assigned, and which is hereby incorporated by reference in its entirety.

In a specific embodiment, the present hybrid photovoltaic/thermal system preferably includes high-temperature thermal components for the hybrid photovoltaic/thermal solar collectors as described above. In a specific embodiment, the hybrid collectors are used for the entire array (without using the traditional unglazed photovoltaic panels), as an example, and should not be limiting the scope of the claims herein. In a specific embodiment, the hybrid system includes a thin film absorber material such as the ones noted herein. In a specific embodiment, the thermal solar system comprises an air handling device, which is coupled to a plenum in the array. The air handling device includes a drive device, which can be a fan, a pump, a blower, a plunger or piston, including combinations of these, and the like. Of course, there can be other variations, modifications, and alternatives.

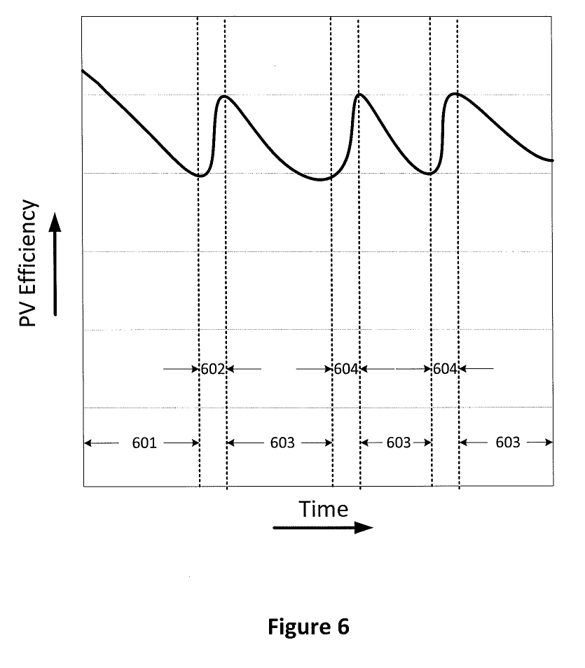

In an alternative specific embodiment, other types of photovoltaic materials are included. As an example, if a photovoltaic material whose efficiency is impacted by temperature is used (such as, but not limited to, a-Si), the possibility exists for the hybrid photovoltaic/thermal system to periodically “self-anneal”, whereby the mechanism that removes heat from the array is turned off, allowing the panels to stagnate at elevated temperature. In a specific embodiment, annealing causes the a-Si (in this example) to recover most of the efficiency lost due to the Staebler-Wronski effect. As merely an example, FIG. 6 shows a simplified characteristic plot of efficiency for a system that is able to self-anneal according to a specific embodiment. This diagram is merely an example, which should not unduly limit the scope of the claims herein. One of ordinary skill in the art would recognize other variations, modifications, and alternatives. After the initial degradation (601), the panel is annealed (602) by stopping the heat-removal mechanism (in the example of an air-based array, the blower would be stopped, causing the panel temperature to increase significantly). This would be cyclic, with a degradation period (603) followed by an annealing period (604).

This process could be incorporated into a control unit. As an illustration, if it is observed that the electrical production of a photovoltaic/thermal system that incorporates glazed a-Si panels begins to degrade from a known benchmark, the working fluid flow rate can be reduced (or stopped), causing the heat removal rate to decrease (or stop). This would drive up the temperature in the glazed photovoltaic module, bringing the a-Si above the annealing temperature. After an appropriate amount of time has passed (dependent upon the temperature achieved within the panel), the system could resume operation and monitor the electrical output of the panel. If a satisfactory recovery of efficiency has not occurred, the process could repeat. In this way a 10 to 30 percent increase in electrical efficiency of the glazed photovoltaic panels may be achieved, yielding a significant increase in electrical production for the system. Again, one of ordinary skill in the art would recognize other variations, modifications, and alternatives.

Additionally, the above sequence of steps provides a method and structure for a hybrid photovoltaic/thermal solar system according to an embodiment of the present invention. In a specific embodiment, the present invention provides a method and resulting structure for a hybrid system, which is efficient and takes advantage of high temperature operation. In a preferred embodiment, the method can be provided using a configured control device in the system using computer software and/or firmware. Other alternatives can also be provided where steps are added, one or more steps are removed, or one or more steps are provided in a different sequence without departing from the scope of the claims herein. It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A solar module assembly comprising:
a substantially transparent or semi-transparent surface provided on a first substrate member;
an absorber material overlying a second substrate member;
a spacing provided between the semi-transparent surface of the first substrate and the second substrate, the second substrate comprising a first side and a second side;
a fluid transport region disposed within a vicinity of either the first side or the second side of the second substrate;
a photovoltaic device configured from at least the absorber material to generate electrical energy; and
a thermal energy device configured from at least the absorber material to generate thermal energy using the a fluid provided in the fluid transport region.

2. The assembly of claim 1 further comprising a low emissivity surface provided to either or both of the first substrate or the second substrate.

3. The assembly of claim 1 further comprising a low emissivity material provided on an intermediary region provided between the first substrate and the second substrate.

4. The assembly of claim 1 wherein the semi-transparent surface is configured to limit thermal transfer from the absorber material to an ambient environment.

5. The assembly of claim 1 wherein the second substrate member is configured to limit thermal transfer from the absorber material to an ambient environment.

6. The assembly of claim 1 further comprising an intermediary region provided within the spacing, the intermediary region being configured to limit thermal transfer from the absorber material to an ambient environment.

7. The assembly of claim 1 further comprising a fluid operably coupled to absorber material to recover thermal energy from the absorber material.

8. The assembly of claim 1 wherein the thermal energy device comprises a fluid to recover thermal energy from the absorber material.

9. The assembly of claim 1 wherein the thermal energy device comprises a fluid to recover thermal energy from the absorber material, the fluid comprising primarily air.

10. The assembly of claim 1 wherein the semi-transparent surface provided on a first substrate member, the absorber material overlying a second substrate member, the spacing provided between the semi-transparent surface of the first substrate and the second substrate to form a fluid transport region, the photovoltaic device configured from at least the absorber material to generate electrical energy and the thermal energy device configured from at least the absorber material to generate thermal energy using the fluid provided in the fluid transport region are configured as a solar module, the solar module being one of a plurality of modules arranged in an array configuration.

11. The assembly of claim 10 wherein the array configuration arranged operatively to function as a single thermal solar module.

12. The assembly of claim 1 wherein the absorber material is selected from at least copper indium gallium diselenide, copper indium diselenide, or cadmium telluride.

13. The assembly of claim 1 wherein the absorber material comprises amorphous silicon.

14. The assembly of claim 1 further comprising a thermoelectric device configured from at least the absorber material.

15. The assembly of claim 1 wherein the absorber material comprises one or more materials.

16. The assembly of claim 1 wherein the absorber material comprises a tandem configuration of photovoltaic devices.

17. The assembly of claim 1 wherein the thermal energy device is configured to convert at least 10% of an incoming flux of electromagnetic radiation into thermal energy.

18. The assembly of claim 1 wherein the thermal energy device is configured to convert at least 25% of an incoming flux of electromagnetic radiation into thermal energy using the fluid.

19. The assembly of claim 1 wherein the photovoltaic device using the absorber material is characterized by a higher efficiency after light soaking.

20. The assembly of claim 1 wherein the photovoltaic device using the absorber material is characterized by a first efficiency and a second efficiency, the second efficiency being achieved at a second temperature, the second temperature being greater than a first temperature associated with the first efficiency.

21. The assembly of claim 1 wherein the first substrate is configured in a planar manner.

22. The assembly of claim 1 wherein the second substrate is configured in a planar manner.

23. The assembly of claim 1 wherein the first substrate is configured in an annular manner.

24. The assembly of claim 1 wherein the second substrate is configured in an annular manner.

25. The assembly of claim 1 wherein the first substrate comprises a planar portion and an annular portion.

26. The assembly of claim 1 wherein the second substrate comprises a planar portion and an annular portion.

27. The assembly of claim 1 wherein the first substrate is irregularly shaped.

28. The assembly of claim 1 wherein the second substrate is irregularly shaped.

29. A method of using a solar module, the method comprising:
providing a solar system comprising:
a substantially transparent or semi-transparent surface provided on a first substrate member;
an absorber material overlying a second substrate member;
a spacing provided between the semi-transparent surface of the first substrate and the second substrate, the second substrate comprising a first side and a second side;
a fluid transport region disposed within a vicinity of either the first side or the second side of the second substrate;
a photovoltaic device configured from at least the absorber material to generate electrical energy; and
a thermal energy device configured from at least the absorber material to generate thermal energy using the a fluid provided in the fluid transport region;
transferring a volume of the fluid through the transport region from a first region to a second region to cause an increase in enthalpy of the volume of the fluid as the volume of the fluid traverses from the first region to the second region; and
using the volume of the fluid.

30. The method of claim 29 wherein the fluid is selected from a liquid or a gas.

31. The method of claim 29 wherein the thermal energy device is characterized with a first efficiency and the photovoltaic device is characterized with a second efficiency, whereupon the first efficiency is equal to or greater than the second efficiency.

32. The method of claim 29 wherein the spacing comprises an air gap.

33. The method of claim 29 wherein the spacing comprising an insulating fluid.

34. The method of claim 29 wherein using the fluid comprises transferring thermal energy from the volume of fluid to water to increase a temperature of the water from a first temperature to a second temperature.

35. The method of claim 29 wherein the using the fluid comprises transferring thermal energy from the volume of fluid to a spatial region within a building structure.

36. The method of claim 29 wherein the using the fluid comprises transferring thermal energy from the volume of the fluid to water in a swimming pool.

37. The method of claim 29 wherein the using the fluid comprises transferring thermal energy from the volume of fluid to a second fluid using a heat exchanger device.

38. The method of claim 29 wherein the transferring of the volume comprises using a drive device to facilitate fluid transport of the fluid from the first region to the second region.

39. The method of claim 38 wherein the drive device comprises a fan.

40. The method of claim 38 wherein the drive device comprises a pump.

41. The method of claim 38 wherein the drive device comprises a blower.

42. The method of claim 38 wherein the drive device comprises a plunger or piston.

43. The method of claim 38 wherein the drive device comprise an air handling unit.
